(19) United States
(12) Patent Application Publication
(10) Pub. No.: US 2025/0180163 A1
(43) Pub. Date: Jun. 5, 2025

(54) OPTO-ELECTRONIC EMERGENCY STOP DEVICE

(71) Applicant: Banner Engineering Corp., Minneapolis, MN (US)

(72) Inventors: Matthew M. Gelineau, Blaine, MN (US); Dean C. Erickson, Wyoming, MN (US)

(21) Appl. No.: 18/843,772

(22) PCT Filed: Mar. 8, 2023
(86) PCT No.: PCT/US2023/014821

§ 371 Date: Sep. 4, 2024

Related U.S. Application Data
(60) Provisional application No. 63/318,319, filed on Mar. 9, 2022.

(51) Int. Cl. F16P 7/02; G02B 26/02; H04B 10/50

(52) U.S. Cl. CPC F16P 7/02; G02B 26/02; H04B 10/501

(57) ABSTRACT

The presently described technology relates to a system having a housing and an optical circuit disposed in the housing. The optical circuit has an emitter configured to emit an emitted optical signal and a receiver configured to receive a received optical signal. An optical transmission pathway extends from the emitter to the receiver. The optical transmission pathway is indirect. A manual actuator is coupled to the housing having an engaged position and a disengaged position. A baffle is fixed to the manual actuator, where the baffle obstructs the optical transmission pathway when the manual actuator is in the engaged position and the baffle is clear of the optical transmission pathway when the manual actuator is in the disengaged position.

### CROSS REFERENCE TO RELATED APPLICATIONS

This application claims the benefit of U.S. Provisional Patent Application No. 63/318,319, filed 9 Mar. 2022, the disclosure of which is incorporated by reference herein in its entirety.

### TECHNOLOGICAL FIELD

The present disclosure is generally related to an emergency stop device. More particularly, the present disclosure is related to an opto-electronic emergency stop device.

### BACKGROUND

Emergency stop devices are generally used to rapidly shut down operating equipment for safety reasons upon engagement of the emergency stop device. Emergency stop devices generally have a mechanical actuator such as a pushbutton and mating switching contacts. The mating switching contacts are in electrical communication with the equipment. The switching contacts can be normally closed (NC) contacts that open when the actuator is engaged (such as by pushing the pushbutton) resulting in shutting down the equipment. The reliability of the switching contacts can be cause for concern, and often such contacts require gold plating to ensure reliable, long-term operation. This can result in a higher system cost.

Further, some emergency stop devices incorporate electronics for additional functions such as illumination or serial communication with other devices. Typically, monitoring of the switching contacts within an emergency stop device is required to facilitate these additional functions. Physically interfacing the switching contacts to the internal electronics on a printed circuit board (PCB) can be cumbersome and often requires a significant amount of hand-wiring, which is prone to wiring mistakes and results in higher labor costs.

### SUMMARY

The technology disclosed herein generally replaces the mechanical switching contacts of the prior art with opto-electronics. Some implementations of the present technology may advantageously reduce the cost associated with emergency stop devices. Furthermore, some implementations of the present technology may advantageously improve the reliability of emergency stop devices.

Some embodiments of the technology disclosed herein relate to a system having a housing and an optical circuit disposed in the housing. The optical circuit has an emitter configured to emit an emitted optical signal, a receiver configured to receive a received optical signal, and an optical transmission pathway extending from the emitter to the receiver. The optical transmission pathway is indirect. A manual actuator is coupled to the housing. The manual actuator has an engaged position and a disengaged position. A baffle is fixed to the manual actuator. The baffle obstructs the optical transmission pathway when the manual actuator is in the engaged position and the baffle is clear of the optical transmission pathway when the manual actuator is in the disengaged position.

In some such embodiments, the emitter defines an emitter axis and the receiver defines a receiver axis and the emitter axis is parallel to the receiver axis. Additionally or alternatively, the optical transmission pathway has a first mirror. Additionally or alternatively, the optical transmission pathway has a second mirror perpendicular to the first mirror. Additionally or alternatively, the manual actuator translates the baffle between the first mirror and the second mirror. Additionally or alternatively, the manual actuator is configured to maintain an engaged position until manual disengagement and the manual actuator is configured to maintain a disengaged position until manual engagement.

Additionally or alternatively, the emitter is configured to emit a pulsed signal in a predetermined pattern. Additionally or alternatively, the system has a controller having a processor in data communication with the optical circuit. The processor is configured to determine whether a signal received by the receiver matches the predetermined pattern of the pulsed signal. The processor is configured to issue a stop command when the signal received by the receiver does not match the predetermined pattern of the pulsed signal. Additionally or alternatively, the system has a controller having a processor in data communication with the optical circuit. The processor is configured to issue a stop command when the receiver does not receive an emitted optical signal. Additionally or alternatively, the device has an indicator assembly coupled to the housing, where the indicator assembly is configured to provide visual indication of the operating state of the system.

Some embodiments of the technology disclosed herein relate to a method. An emitter emits an emitted optical signal within a housing. The emitted optical signal is transmitted along an optical transmission pathway within the housing from the emitter towards a receiver via a mirror. The optical transmission pathway is obstructed, resulting from engagement of a manual actuator. The system identifies a lack of receipt of the emitted optical signal by the receiver and issues a stop command by a controller upon identification of the lack of receipt of the emitted optical signal.

In some such embodiments, obstructing the optical transmission pathway includes translating a baffle across the optical transmission pathway. Additionally or alternatively, obstructing the optical transmission pathway includes translating the optical transmission pathway across a baffle. Additionally or alternatively, obstructing the optical transmission pathway includes translating the mirror. Additionally or alternatively, an electronic output signal is provided to the controller by the receiver correlating to a received optical signal.

Additionally or alternatively, identifying lack of receipt of the emitted optical signal by the receiver includes determining that the emitted optical signal is not received by the receiver by a processor comparing the electronic output signal to the emitted optical signal and determining that the electronic output signal does not match the emitted optical signal. Additionally or alternatively, the optical signal has a predetermined pattern. Additionally or alternatively, the electronic output signal has a different pattern than the predetermined pattern. Additionally or alternatively, a stop command is withheld by a controller when the emitted optical signal is received by the receiver. Additionally or alternatively, an electronic output signal is provided to the controller from the receiver correlating to a received optical signal, where the emitted optical signal has a predetermined pattern and the electronic output signal has the same pattern as the predetermined pattern. Additionally or alternatively, a run command is issued by the processor. Additionally or alternatively, an indicator assembly is switched from a first state of illumination to a second state of illumination upon the identifying lack of receipt of the emitted optical signal by the receiver.

The above summary is not intended to describe each embodiment or every implementation. Rather, a more complete understanding of illustrative embodiments will become apparent and appreciated by reference to the following Detailed Description of Exemplary Embodiments and claims in view of the accompanying figures of the drawing.

### BRIEF DESCRIPTION OF THE DRAWINGS

The present technology may be more completely understood and appreciated in consideration of the following detailed description of various embodiments in connection with the accompanying drawings.

FIG. 1 is an example emergency stop device consistent with various embodiments, where the emergency stop device is in a disengaged position.

FIG. 2 is the example emergency stop device of FIG. 1, where the emergency stop device is in an engaged position.

FIG. 3 is another example emergency stop device consistent with some embodiments.

FIG. 4 is yet another example emergency stop device consistent with embodiments.

FIG. 5 is a schematic diagram of an example system consistent with the technology disclosed herein.

FIG. 6 is a flow chart depicting an example method consistent with the technology disclosed herein.

The figures are rendered primarily for clarity and, as a result, are not necessarily drawn to scale. Moreover, various structure/components, including but not limited to fasteners, electrical components (wiring, cables, etc.), and the like, may be shown diagrammatically or removed from some or all of the views to better illustrate aspects of the depicted embodiments, or where inclusion of such structure/components is not necessary to an understanding of the various exemplary embodiments described herein. The lack of illustration/description of such structure/components in a particular figure is, however, not to be interpreted as limiting the scope of the various embodiments in any way.

### DETAILED DESCRIPTION

Emergency stop devices of the technology disclosed herein generally incorporates an optical circuit having an emitter configured to emit an emitted optical signal and a receiver configured to receive a received optical signal. The receiver is configured to provide an electronic output signal correlating with the received optical signal. An optical transmission pathway is defined from the emitter to the receiver. During normal operation, the optical transmission pathway is unobstructed so the received optical signal and, therefore, the electronic output signal correlating with the received optical signal matches the emitted optical signal. During a stop condition, the optical transmission pathway is obstructed, and so the electronic output signal correlating with the received optical signal does not match the emitted optical signal because the receiver is no longer receiving the emitted optical signal. Upon identifying such a stop condition, the system sends a stop command to external equipment that is operatively coupled to the emergency stop device.

A stop condition can include a fault condition, which is where there is some damage or defect to the system that prevents transmission of an optical signal from the emitter to the receiver along the optical transmission pathway. A stop condition can also include manual engagement of the emergency stop device by a user. A user can manually engage the emergency stop device when, for example, they observe a potential danger associated with further operation of the equipment that is operably coupled to the emergency stop device. Manually engaging the manual actuator can cause an obstruction along the optical transmission pathway, which prevents the receiver receiving the emitted optical signal. Further aspects of the present technology are described in detail below.

### Exemplary Emergency Stop Devices

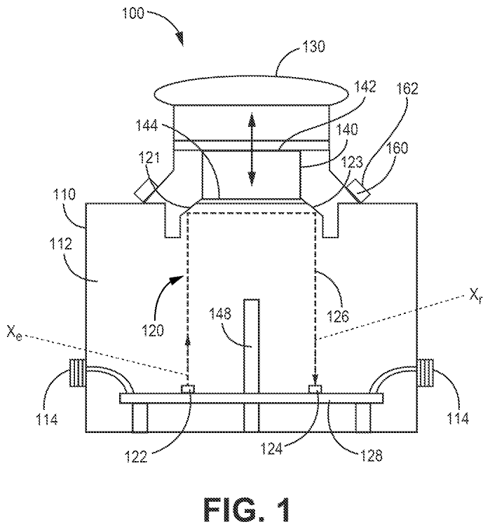

FIG. 1 is an example emergency stop device 100 consistent with various embodiments. The emergency stop device 100 is generally configured to shut down equipment that is electrically coupled thereto upon manual engagement of the emergency stop device 100 by a user. The emergency stop device 100 has a housing 110, an optical circuit 120 disposed in the housing 110, a manual actuator 130, and a baffle 140 fixed to the manual actuator 130.

The housing 110 of the emergency stop device 100 is generally configured to house various components of the system including, for example, the optical circuit 120 and the baffle 140. The housing 110 generally defines a housing cavity 112 that receives one or more components. The housing 110 can be constructed of various materials and combinations of materials generally known in the art. In some embodiments, the housing 110 is substantially opaque. Such a configuration may advantageously limit entry of ambient light into the housing 110, which may reduce ambient light interference with the optical circuit 120.

The optical circuit 120 is disposed in the housing 110. The optical circuit 120 is generally configured to provide an electronic output signal indicative of a current operating state of the emergency stop device 100. In some embodiments, the optical circuit 120 provides a first electronic output signal when the emergency stop device 100 and, in particular, the manual actuator 130, is engaged. Engagement of the manual actuator 130 creates a stop condition. In some such embodiments the optical circuit 120 provides a second electronic output signal when the emergency stop device 100 and, in particular, the manual actuator 130, is disengaged. In some such embodiments, the optical circuit 120 is also configured to provide the first electronic output signal when a fault condition occurs, which is described in more detail below.

The optical circuit 120 generally has an emitter 122, a receiver 124, and an optical transmission pathway 126 extending from the emitter 122 to the receiver 124. The emitter 122 is generally configured to emit an optical signal. The emitter 122 has an emitter axis xₑ that defines the linear outward direction of the emitted signal from the emitter 122. The emitter 122 can be configured to emit a variety of different types of optical signals. For example, the emitter 122 can be configured to generate infrared light or laser light. The emitter 122 can be configured to emit a light in a predetermined pattern, such as a flashing or pulsating light at a particular frequency. In some embodiments, however, the emitter 122 is configured to emit a continuous light. The emitter 122 is a light emitting diode (LED) in some embodiments. In some other embodiments the emitter 122 is vertical cavity surface emitting laser (VCSEL). The emitter 122 can be configured to modulate the optical signal such that the receiver 124 can discriminate against background light. For example, the emitter 122 can be configured to generate and transmit an optical signal at a predetermined pattern (e.g., a frequency of 100 kHz).

The receiver 124 is generally configured to receive optical signals. The receiver 124 has a receiver axis xᵣ that defines the general linear direction of the optical signal received by the receiver 124. In various embodiments, the receiver 124 is configured to convert a received optical signal to an electronic output signal. In various embodiments the strength and pattern of the received optical signal directly correlates to the strength and pattern of the electronic output signal. In some embodiments, the receiver 124 includes a notch filter for receiving a modulated light signal. In some embodiments the receiver 124 incorporates a narrow band filter to limit detection (and, therefore, electronic signal generation) to an optical signal with a predetermined pattern. In some such embodiments, the receiver 124 is configured to generate an electronic output signal upon receiving an optical signal with the predetermined pattern. Such a configuration may advantageously prevent device interference by optical signals that are not emitted by the emitter 122, such as ambient light.

In various embodiments, the optical transmission pathway 126 from the emitter 122 to the receiver 124 is indirect, meaning that the optical transmission pathway 126 is not a straight line. In various examples, at least one mirror defines a portion of the optical transmission pathway 126 between the emitter 122 and the receiver 124. A “mirror” is defined herein as a reflective surface. Mirrors consistent with the technology disclosed herein are generally configured for specular reflection. In the current example, a first mirror 121 is disposed along the optical transmission pathway 126 that is configured to receive the optical signal from the emitter 122. In some embodiments, the first mirror 121 is configured to transmit the optical signal to a second mirror 123, such that the second mirror 123 is disposed along the optical transmission pathway 126. In some embodiments, the second mirror 123 is configured to receive the optical signal from the first mirror 121. In some embodiments, the second mirror 123 is configured to transmit the optical signal to the receiver 124.

In the current example, the emitter 122 and the receiver 124 are coupled to a printed circuit board (PCB) 128. The emitter axis xₑ and the receiver axis xᵣ are each perpendicular to the PCB 128. As such, the emitter axis xₑ and the receiver axis xᵣ are parallel. The first mirror 121 is oriented at a 45-degree angle to the emitter axis xₑ. The second mirror 123 is perpendicular to the first mirror 121. The second mirror 123 is oriented at a 45-degree angle to the receiver axis xᵣ. In some other embodiments the emitter axis xₑ and the receiver axis xᵣ are non-parallel. In some such embodiments the emitter 122 and the receiver 124 are coupled to separate PCBs. In some embodiments the emitter axis xₑ and the receiver axis xᵣ are perpendicular, and a single mirror is disposed along the optical transmission pathway to transmit light from the emitter 122 to the receiver 124. In such an example the mirror can be oriented 45 degrees relative to the emitter axis xₑ and the receiver axis xᵣ.

In various embodiments, incorrect alignment of the manual actuator 130 on the housing 110 may result in misalignment of one or more components defining the optical transmission pathway 126. Such misalignment is a fault condition that prevents the optical signal emitted by the emitter 122 from being received by the receiver 124. In such a fault condition the receiver 124 is configured to provide an electronic output signal consistent with not having received the emitted optical signal, which may be consistent with the first electronic output signal indicating a stop condition or a third electronic output signal indicating a second stop condition different than the stop condition indicated by the first electronic output signal. Incorrect alignment between the manual actuator 130 and the housing 110 can result from, for example, mechanical impact, improper installation, or defect of one or more components.

The manual actuator 130 is generally coupled to the housing 110. The manual actuator 130 is generally configured to be manually engaged by a user to stop equipment operation that is operably coupled thereto. The manual actuator 130 generally has a disengaged position and an engaged position. In various embodiments the manual actuator 130 is a push button. The manual actuator 130 is configured to be pushed by a user. In some embodiments where the manual actuator 130 is a push button, the push button is extended in the disengaged position and depressed to the engaged position.

In various embodiments, the manual actuator 130 is configured to maintain a disengaged position until manual engagement (such as by depressing the push button). In various embodiments, upon engagement, the manual actuator 130 is configured to maintain an engaged position until manually disengaged. For example, in some embodiments the manual actuator 130 is coupled to a latch that is configured to releasably couple to the housing 110 or another component upon manual engagement. The latch can maintain the manual actuator 130 in an engaged position until manual disengagement of the latch. In some embodiments the latch is configured to be manually released by a user such as when, for example, emergency conditions have been resolved and the equipment can be started up again. In some embodiments where the manual actuator is a push button, the latch can be released by a user by pressing the push button a second time. In another example, the pushbutton can be twisted to release the latch and disengage the manual release mechanism. Other configurations are also possible that are generally known.

The baffle 140 is fixed to the manual actuator 130. The baffle 140 is configured to selectively obstruct the optical transmission pathway 126. In particular, in various embodiments the baffle 140 obstructs the optical transmission pathway 126 when the manual actuator 130 is in the engaged position. In such embodiments, the baffle 140 is clear of the optical transmission pathway 126 (such as visible in FIG. 1) when the manual actuator 130 is in the disengaged position. When the baffle 140 is clear of the optical transmission pathway 126, the receiver 124 can receive the optical signal from the emitter 122, and the receiver 124 provides a first electronic output signal that is an electrical signal resulting from the received optical signal. When the baffle 140 obstructs the optical transmission pathway 126 the receiver 124 does not receive the optical signal from the emitter 122 and the receiver 124 provides a second electronic output signal that is an electrical signal resulting from the emitted optical signal not being received. It should be understood that the second electronic output signal can be a lack of an electrical signal resulting from a lack of receipt of any optical signal by the receiver.

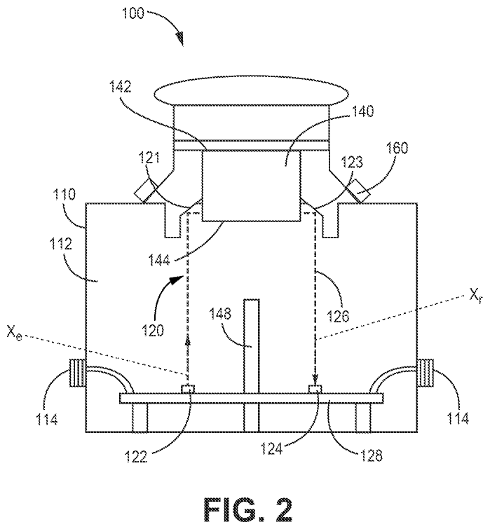

In various embodiments where the manual actuator 130 is a push button, the manual actuator 130 can be configured to translate the baffle 140 through the optical transmission pathway 126. In the current example, engaging the manual actuator 130 translates the baffle between the first mirror 121 and the second mirror 123, which is visible in FIG. 2. More particularly, the baffle 140 has a first end 142 fixed to the manual actuator 130. The baffle 140 extends axially towards the interior of the housing 110 and has a second end 144 opposite the first end 142. During engagement of the manual actuator 130, the second end 144 translates through the optical transmission pathway 126. Upon engagement of the manual actuator 130, the first end 142 and the second end 144 of the baffle 140 are on opposite sides of the optical transmission pathway 126. When disengaged, the first end 142 and the second end 144 are on the same side of the optical transmission pathway 126.

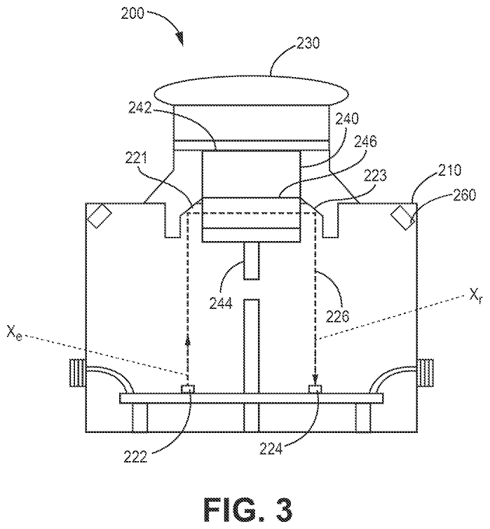

The baffle can have alternate configurations. In one example shown with reference to FIG. 3, which is otherwise consistent with the description of FIGS. 1-2, the device 200 has a baffle 240 having a first end 242 coupled to a manual actuator 230 and a second end 244 opposite the first end 242. The baffle 240 extends across the optical transmission pathway 226 such that the second end 244 is on the opposite side of the optical transmission pathway 226 when the manual actuator 230 is both in the engaged position and the disengaged position. In this example, the baffle 240 defines a transmission opening 246 between the first end 242 and the second end 244 that accommodates optical transmission along the optical transmission pathway 226 when the manual actuator 230 is in a disengaged position. As such, despite extending across the optical transmission pathway 226, the baffle 240 is clear of the optical transmission pathway 226 when the manual actuator 230 is in a disengaged position. However, when the manual actuator 230 is in an engaged position, the transmission opening 246 is translated out of alignment with the optical transmission pathway 226, such that the baffle 240 obstructs the optical transmission pathway 226.

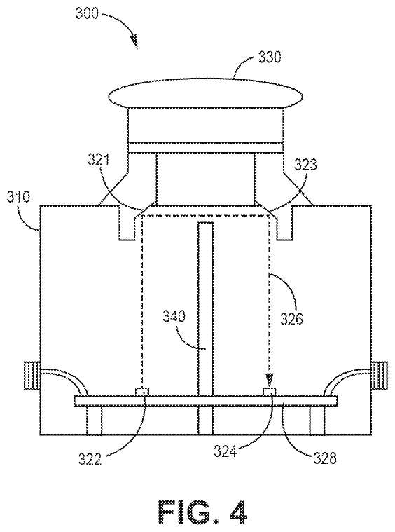

In should be appreciated that the baffle 240 can be configured to translate between other components along the optical transmission pathway 226, such as between an emitter 222 and a first mirror 221 or between a receiver 224 and a second mirror 223. In yet other configurations, the baffle can be stationary and components defining the optical transmission pathway can be configured to translate to a position where the baffle obstructs the optical transmission pathway, such as depicted in FIG. 4.

FIG. 4 can be consistent with the descriptions above except as described here. In this example device 300 a first mirror 321 and the second mirror 323 are fixed to the manual actuator 330 that is coupled to a housing 310. A baffle 340 is disposed in the housing 310 between an emitter 322 and a receiver 324. By way of example, the baffle 340 can be directly coupled to the housing 310 or can be coupled to a PCB 328 that has one or both of the emitter 322 and receiver 324. In the current example, the baffle 340 extends in the axial direction from a position laterally between the emitter 322 and receiver 324 towards the manual actuator 330.

When the manual actuator 330 is in a disengaged position, the baffle 340 is clear of the optical transmission pathway 326. When the manual actuator 330 is in an engaged position, the baffle 340 obstructs the optical transmission pathway 326. In particular, the first mirror 321 and the second mirror 323 translate in the axial direction towards the PCB 328 to a location where that the first mirror 321 and the second mirror 323 are on opposite sides of the baffle 340. It is noted that a variation of the current design could be used where the baffle extends axially across the optical transmission pathway (326) but has a transmission opening similar to that shown in FIG. 3, that accommodates the optical transmission pathway 326 when the manual actuator is disengaged, and the mirrors move out of alignment with such a transmission opening when the manual actuator is engaged such that the optical transmission pathway 326 is obstructed.

Returning again to FIGS. 1 and 2, it is noted that the device 100 incorporates a secondary baffle 148 that extends axially between the emitter 122 and the receiver 124. The secondary baffle 148 is configured to physically separate the emitter 122 and the receiver 124 to reduce interference caused by optical signals transmitted outside of the optical transmission pathway 126. In some embodiments the secondary baffle 148 can be omitted.

In various embodiments the emergency stop device 100 has a connection interface 114 configured to releasably couple to an electrical coupling element that establishes electrical communication between a power source and the optical circuit 120. The connection interface 114 may, for example, be a commercially available component. The connection interface 114 can also be configured for data transmission between the optical circuit 120, such as the emitter 122 and/or receiver 124, and a controller. The controller can be a programmable logic controller (PLC) as an example. The controller is in operable communication with electrically powered equipment and is configured to stop operation of the equipment when stop conditions are met, such as when the emergency stop device 100 is engaged. In various embodiments, multiple emergency stop devices are configured to be operably coupled in series with a single controller. Such a configuration may advantageously simplify wiring complexity, reduce necessary wiring, and/or reduce the number of interface terminals used on the controller.

In some other embodiments the emergency stop device can be configured to directly stop operation of equipment that is operably coupled thereto rather than through a controller. In such embodiments, a force-guided relay output can be incorporated in the emergency stop device that directly interfaces with the relevant equipment.

In the example depicted in FIGS. 1 and 2, The emergency stop device 100 has an indicator assembly 160 coupled to the housing 110. The indicator assembly 160 is configured to provide visual indication of the operating state of the device 100. In the current example, the indicator assembly 160 is disposed circumferentially around at least a portion of the housing 110. In particular, the indicator assembly 160 is coupled to the housing 110 circumferentially around the manual actuator 130. In the current example, the indicator assembly 160 has an emitting surface 162 that is configured to direct the generated light radially outward from the housing 110. In this specific example, the emitting surface 162 of the indicator assembly 160 is also configured to direct the generated light axially outward from the housing 110, as well. Other configurations are certainly possible. In some embodiments, such as that depicted in FIG. 3, an indicator assembly 260 is disposed within the housing 210 and at least a portion of the housing 210 is constructed of an optically transparent material to accommodate light transmission from the indicator assembly to the outside environment.

Returning to FIGS. 1-2, the indicator assembly 160 can be configured to emit light in a plurality of different states of illumination (such as a plurality of colors and/or pulse patterns observable to a human eye) to communicate the current operating state of the system to a user. As an example, a first operating state can be during an absence of a stop condition. A second operating state can be during the presence of a stop condition and, more particularly, when the optical signal received by the receiver does not match the optical signal emitted by the emitter. In some embodiments there is a third operating state also consistent with a stop condition when the emitter 122 malfunctions, such as if the emitter 122 does not emit an emitted optical signal. In some embodiments the indicator assembly 160 is configured to differentiate among the different operating states with different states of illumination. For example, a first state of illumination can be solid green light. A second state of illumination can be a solid red light. A third state of illumination can be a flashing red light. In some embodiments, a state of illumination can include a flashing or solid yellow or orange light. Other states of illumination are also contemplated.

In various embodiments the indicator assembly 160 is a multi-color LED illuminator, although other types of indicator assemblies are certainly contemplated. In some embodiments the indicator assembly 160 can include a speaker to audibly indicate a stop condition, as an example. In some embodiments the indicator assembly 160 is a single cohesive component, such as an annular illumination device. In other embodiments the indicator assembly 160 includes a plurality of discrete illumination devices that are electrically coupled to each other and disposed in a series around at least a portion of the emergency stop device 100. The indicator assembly 160 is generally electrically coupled to a power source. In some embodiments the indicator assembly 160 is operatively coupled to the PCB 128. In various embodiments the indicator assembly 160 can be operatively coupled to a processing device, which will be described in more detail below.

### Exemplary Emergency Stop Systems

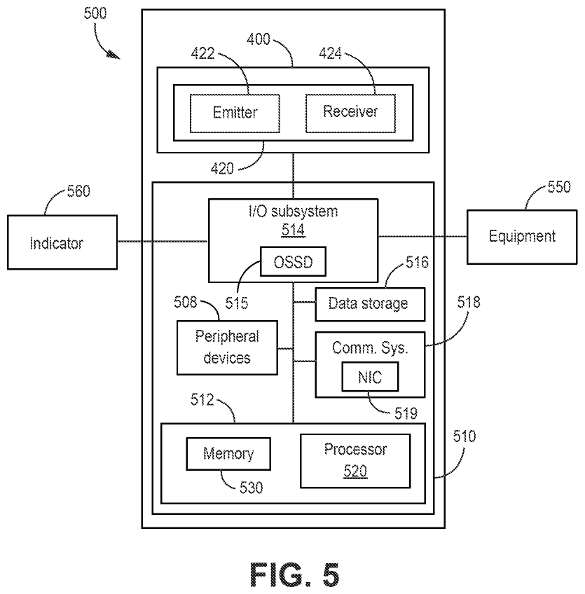

FIG. 5 depicts an example system 500 consistent with various embodiments. The system 500 has an emergency stop device 400 having an optical circuit 420 that is in electrical and data communication with controller 510. The controller 510 is in operative communication with external equipment 550, such as an operating machine in a factory or warehouse setting.

The controller 510 may be embodied as a type of device, appliance, computer, apparatus or controller of a computerized apparatus, or other apparatus capable of communicating with other edge, networking, or endpoint components. For example, a controller may be embodied as a personal computer, server, smartphone, a mobile compute device, a smart appliance, a self-contained device having an outer case, shell, etc., an emergency stop device or component thereof, or other device or system capable of performing the described functions.

In the simplified example depicted in FIG. 5, a controller 510 includes processing circuitry 512, an input/output (I/O) subsystem 514, data storage device 516, communication circuitry 518, and, optionally, one or more peripheral devices 508. In other examples, respective compute devices may include other or additional components, such as those typically found in a computer (e.g., a display, peripheral devices such as keyboards, etc.). Additionally, in some examples, one or more of the illustrative components may be incorporated in, or otherwise form a portion of, another component such as the emergency stop device 400.

The controller 510 may be embodied as any type of engine, device, or collection of devices capable of performing various processing and controlling functions. In some examples, the controller 510 may be embodied as a single device such as an integrated circuit, an embedded system, a field-programmable gate array (FPGA), a system-on-a-chip (SOC), or other integrated system or device. In the illustrative example, the controller 510 includes or is embodied as a processor 520 and a memory 530. The processor 520 may be embodied as any type of processor capable of performing the functions described herein (e.g., executing an application). For example, the processor 520 may be embodied as a multi-core processor(s), a microcontroller, or other processor or processing/controlling circuit. In some examples, the processor 520 may be embodied as, include, or be coupled to an FPGA, an application specific integrated circuit (ASIC), reconfigurable hardware or hardware circuitry, or other specialized hardware to facilitate performance of the functions described herein.

The memory 530 may be embodied as any type of volatile (e.g., dynamic random-access memory (DRAM), etc.) or non-volatile memory or data storage capable of performing the functions described herein. Volatile memory may be a storage medium that requires power to maintain the state of data stored by the medium. Non-limiting examples of volatile memory may include various types of random-access memory (RAM), such as DRAM or static random-access memory (SRAM). One particular type of DRAM that may be used in a memory module is synchronous dynamic random-access memory (SDRAM).

In an example, the memory 530 is a block addressable memory device, such as those based on NAND or NOR technologies. The memory device may refer to the die itself and/or to a packaged memory product. In some examples, all or a portion of the memory 530 may be integrated into the processor 520. The memory 530 may store various software and data used during operation such as one or more applications, data operated on by the application(s), libraries, and drivers.

The processing circuitry 512 is communicatively coupled to other components of the controller 510 via the I/O subsystem 514, which may be embodied as circuitry and/or components to facilitate input/output operations with the processing circuitry 512 (e.g., with the processor 520 and/or the memory 530) and other components of the processing circuitry 512. For example, the I/O subsystem 514 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some examples, the I/O subsystem 514 may form a portion of a system-on-a-chip (SoC) and be incorporated, along with one or more of the processor 520, the memory 530, and other components of the processing circuitry 512, into the processing circuitry 512.

The I/O subsystem 514 is configured to receive inputs from, among other devices and apparatuses, the emergency stop device 400 and, in particular, the optical circuit 420 of the emergency stop device 400. In various embodiments the processor 520 is in data communication with the optical circuit 420, such as through the I/O subsystem 514. The processor 520 is configured to receive electronic output signals from the receiver 424. The electronic output signals may indicate information regarding characteristics (e.g., amplitude) of optical signals received from a receiver. The electronic output signals may indicate a pattern of the optical signals received by the receiver 424 including a pulse signature, frequency, or wavelength, as examples.

The processor 520 is also in operative communication with the external equipment 550 through the I/O subsystem 514. The processor 520 is configured to issue a stop command, such as through an OSSD (output signal switching device) 515 to the equipment 550 when a stop condition exists. In various embodiments the processor 520 is configured to issue a run command (such as through an OSSD) to the equipment 550 when a stop condition does not exist.

In some embodiments, the processor 520 is configured to determine, in accordance with program instructions stored in the memory 530, whether an optical signal received by the receiver 424 matches the optical signal that the emitter 422 is configured to emit. For example, the emitter 422 can be configured to emit a predetermined pattern, such as frequency, of an optical signal. In some such embodiments, when the optical signal received by the receiver 424 does not match the emitted optical signal (such as the predetermined pattern of the signal), the processor 520 is configured to issue a stop command. Further, the processor 520 is configured to identify when the receiver 424 does not receive an optical signal at all. In such a circumstance, the processor 520 is configured to the issue a stop command. In some such embodiments, when the processor 520 identifies that the optical signal received by the receiver 424 does match the emitted signal (such as a predetermined pattern of the pulsed signal), the system is in a run condition and the processor 520 is configured to withhold a stop command. The processor 520 can be configured to issue a run command, in some embodiments.

In various embodiments the controller 510 can incorporate redundant processing channels in the processor 520 to monitor the received signals. Each redundant processing channel can be in communication with a separate OSSD. In various implementations, if one or both of the redundant processing channels identifies a stop condition, the controller 510 is configured to issue a stop command.

In some implementations, when the processor issues a stop command (via one or more processing channels), the emergency stop system 500 locks out to prevent restarting of the equipment until the stop condition is resolved. In some embodiments, the lock-out can be cleared by repairing a fault condition (where there has been a fault). In some embodiments the lock-out can additionally or alternatively be cleared by resetting the system by a power cycle or by a predefined reset sequence. In some implementations, if the fault condition persists, the emergency stop device 400 will maintain its locked out state.

The one or more illustrative data storage devices 516 may be embodied as any type of devices configured for short-term or long-term storage of data such as, for example, memory devices and circuits, memory cards, hard disk drives, solid-state drives, or other data storage devices. Individual data storage devices 516 may include a system partition that stores data and firmware code for the data storage device 516. Individual data storage devices 516 may also include one or more operating system partitions that store data files and executables for operating systems depending on, for example, the type of controller 510.

The communication circuitry 518 may be embodied as any communication circuit, device, or collection thereof, capable of enabling communications over a network between the processing circuitry 512 and another processing device (e.g., an edge gateway of an implementing edge computing system). The communication circuitry 518 may be configured to use any one or more communication technology (e.g., wired or wireless communications) and associated protocols (e.g., a cellular networking protocol such a 3GPP 4G or 5G standard, a wireless local area network protocol such as IEEE 802.11/Wi-Fi®, a wireless wide area network protocol, Ethernet, Bluetooth®, Bluetooth Low Energy, a IoT protocol such as IEEE 802.15.4 or ZigBee®, low-power wide-area network (LPWAN) or low-power wide-area (LPWA) protocols, etc.) to effect such communication.

The illustrative communication circuitry 518 can include a network interface controller (NIC) 519. The NIC 519 may be embodied as one or more add-in-boards, daughter cards, network interface cards, controller chips, chipsets, or other devices that may be used by the controller 510 to connect with another processing device. In some examples, the NIC 519 may be embodied as part of a system-on-a-chip (SoC) that includes one or more processors or included on a multichip package that also contains one or more processors. In some examples, the NIC 519 may include a local processor (not shown) and/or a local memory (not shown). In such examples, the local processor of the NIC 519 may be capable of performing one or more of the functions of the processing circuitry 512 described herein. Additionally, or alternatively, in such examples, the local memory of the NIC 519 may be integrated into one or more components of the client compute node at the board level, socket level, chip level, and/or other levels.

Additionally, in some examples, a respective controller 510 may include one or more peripheral devices 508. Such peripheral devices 508 may include any type of peripheral device found in a compute device or server such as audio input devices (e.g., speakers), a display, other input/output devices, interface devices, and/or other peripheral devices, depending on the controller 510. In further examples, the controller 510 may be embodied by a respective edge compute node (whether a client, gateway, or aggregation node) in an edge computing system or like forms of appliances, computers, subsystems, circuitry, or other components.

In some embodiments the system 500 has an indicator assembly 560 that is configured to provide visual indication of the operating state of the system. In such embodiments, the processor 520 is in operative communication with the indicator assembly 560, such as through the I/O subsystem 514 and more particularly, such as through an OSSD 515. The processor 520 can be configured to switch the indicator assembly 560 among the different states of illumination (discussed above with reference to FIGS. 1-2) in response to a changing operating state of the system 500.

The indicator assembly 560 can be configured to be mounted for viewing within the operating environment of the system 500. In some embodiments, the indicator assembly 560 is coupled to the emergency stop device 400 as discussed above with reference to FIGS. 1-2.

Instructions for implementing any of the methods described herein can be stored on a machine-readable medium. The machine-readable medium can include any tangible medium that is capable of storing, encoding, or carrying instructions for execution by a machine and that cause the machine to perform any one or more of the methodologies of the present disclosure or that is capable of storing, encoding or carrying data structures utilized by or associated with such instructions. A “machine-readable medium” thus may include but is not limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks. The instructions embodied by a machine-readable medium may further be transmitted or received over a communications network using a transmission medium via a network interface device utilizing any one of several transfer protocols (e.g., Hypertext Transfer Protocol (HTTP)).

A machine-readable medium may be provided by a storage device or other apparatus which is capable of hosting data in a non-transitory format. In an example, information stored or otherwise provided on a machine-readable medium may be representative of instructions, such as instructions themselves or a format from which the instructions may be derived. This format from which the instructions may be derived may include source code, encoded instructions (e.g., in compressed or encrypted form), packaged instructions (e.g., split into multiple packages), or the like. The information representative of the instructions in the machine-readable medium may be processed by processing circuitry into the instructions to implement any of the operations discussed herein. For example, deriving the instructions from the information (e.g., processing by the processing circuitry) may include: compiling (e.g., from source code, object code, etc.), interpreting, loading, organizing (e.g., dynamically, or statically linking), encoding, decoding, encrypting, unencrypting, packaging, unpackaging, or otherwise manipulating the information into the instructions.

In an example, the derivation of the instructions may include assembly, compilation, or interpretation of the information (e.g., by the processing circuitry) to create the instructions from some intermediate or preprocessed format provided by the machine-readable medium. The information, when provided in multiple parts, may be combined, unpacked, and modified to create the instructions. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable, etc.) at a local machine, and executed by the local machine.

It is noted that, while in the currently described system the emergency stop device 400 is in data and electrical communication with a controller 510 that operably controls the external equipment, in some other embodiments the emergency stop device incorporates force-guided relay outputs that are configured for direct interfacing with and control of the external equipment.

### Exemplary Methods

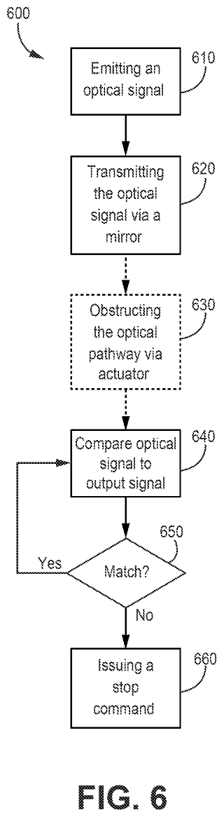

FIG. 6 illustrates a method 600 for using an emergency stop system in accordance with various embodiments. Operations of the method 600 can be performed by the emergency stop devices described herein, the processing circuitry 512 (FIG. 5), or other components of the emergency stop system 500 (FIG. 5). In this method 600 an optical signal is emitted 610, the optical signal is transmitted via a mirror 620, the optical transmission pathway is obstructed 630, the optical signal is compared to an output signal 640, and a stop command is issued 650.

The optical signal is generally emitted by an emitter 610, where emitters have been discussed in detail elsewhere herein. The emitter is generally disposed within a housing, also discussed elsewhere herein. The optical signal can be a continuous signal in some embodiments. In other embodiments the optical signal is emitted 610 in pulses at a predetermined frequency or in another predetermined pattern. In some embodiments the optical signal can be consistent with optical signals discussed elsewhere herein.

The optical signal is generally transmitted along an optical transmission pathway within the housing via a mirror 620. In various embodiments a first mirror and a second mirror define portions of the optical transmission pathway and are configured to transmit the optical signal. The optical signal is transmitted along the optical transmission pathway from the emitter to a receiver via the one or more mirrors. The receiver receives a received optical signal. In various embodiments, the receiver generates an electronic output signal that correlates with the received optical signal. When the optical transmission pathway is unobstructed and a fault condition does not exist, the received optical signal is the emitted optical signal, and so the electronic output signal generated by the receiver matches the emitted optical signal. When the optical transmission pathway is obstructed or a fault condition exists, the received optical signal is not the emitted optical signal, and so the electronic output signal generated by the receiver does not match the emitted optical signal.

Obstructing the optical transmission pathway 630 can be accomplished via a manual actuator. The manual actuator can be manually engaged through a variety of approaches discussed above. In examples, the manual actuator is a pushbutton that is manually engaged by depressing the pushbutton. In various embodiments the manual actuator is mechanically latched upon engagement such that the manual actuator maintains an engaged position upon manual engagement. The optical transmission pathway 630 can be obstructed through a variety of approaches, some of which have been discussed above. For example, obstructing the optical transmission pathway 630 can include translating a baffle across the optical transmission pathway, such as discussed above with reference to FIGS. 1-3. As another example, obstructing the optical transmission pathway 630 can include translating the optical transmission pathway across the baffle, such as shown and described with reference to FIG. 4. As another example, obstructing the optical transmission pathway 630 can include translating the mirror to a different position. FIG. 4 depicts one embodiment where a mirror is translated to obstruct the optical transmission pathway 630. As an alternate example, one or both of the mirrors can be translated outside of the optical transmission pathway to obstruct the optical transmission pathway.

The optical signal is compared to the output signal 640 to determine whether the signals match 650. Such a comparison can identify that the emitted optical signal was not received by the receiver. A processor can receive the electronic output signal from the receiver and compare the emitted optical signal to the electronic output signal. When the output signal does not match the emitted optical signal, then the processor can determine that the emitted optical signal was not received by the receiver, such as when the optical pathway is obstructed via the actuator 630. For example, the processor can determine that the electronic output signal does not match the emitted optical signal when the electronic output signal has a different pattern, such as a different frequency, than the predetermined pattern of the emitted optical signal. As another example, the processor can determine that the electronic output signal does not match the emitted optical signal when there is no detected electronic output signal. A stop command is issued 650 by a controller upon identification that the emitted optical signal was not received by the receiver.

In various embodiments, a stop command is withheld by the controller when the output signal matches emitted optical signal is received by the receiver, such as when the optical pathway is unobstructed and another fault condition does not exist. The processor can make such a determination when the emitted optical signal has a predetermined pattern and the electronic output signal, which correlates to the received optical signal, has the same pattern as the predetermined pattern (as an example). Withholding the stop command can be consistent with the controller issuing a run command.

In some embodiments where the system incorporates an indicator assembly, the indicator assembly can generally indicate the operating state of the system. When the processor determines that an optical signal has been emitted and that the emitted optical signal matches the received optical signal, the indicator assembly can have a first state of illumination. When the processor determines that the electronic output signal does not match the emitted optical signal, which indicates the lack of receipt of the emitted optical signal by the receiver, the indicator assembly can have a different state of illumination corresponding to the stop condition. In some embodiments, the indicator assembly is switched from the first state of illumination to a second state of illumination when the processor determines that the output signal does not match the emitted optical signal. In some embodiments the indicator assembly is switched to a third state of illumination when the processor determines that the emitter is not emitting an optical signal.

### EXEMPLARY EMBODIMENTS

Embodiment 1. A system comprising:
a housing;
an optical circuit disposed in the housing, the optical circuit comprising an emitter configured to emit an emitted optical signal, a receiver configured to receive a received optical signal, and an optical transmission pathway extending from the emitter to the receiver, wherein the optical transmission pathway is indirect; a manual actuator coupled to the housing having an engaged position and a disengaged position; and
a baffle fixed to the manual actuator, wherein the baffle obstructs the optical transmission pathway when the manual actuator is in the engaged position and the baffle is clear of the optical transmission pathway when the manual actuator is in the disengaged position.
Embodiment 2. The system of any one of embodiments 1 and 3-10, wherein the emitter defines an emitter axis and the receiver defines a receiver axis and the emitter axis is parallel to the receiver axis.
Embodiment 3. The system of any one of embodiments 1-2 and 4-10, wherein the optical transmission pathway comprises a first mirror.
Embodiment 4. The system of embodiments 3, wherein the optical transmission pathway comprises a second mirror perpendicular to the first mirror.
Embodiment 5. The system of embodiment 4, wherein engaging the manual actuator translates the baffle between the first mirror and the second mirror.
Embodiment 6. The system of any one of embodiments 1-5 and 7-10, wherein the manual actuator is configured to maintain an engaged position until manual disengagement and the manual actuator is configured to maintain a disengaged position until manual engagement.
Embodiment 7. The system of any one of embodiments 1-6 and 8-10, wherein the emitter is configured to emit a pulsed signal in a predetermined pattern.
Embodiment 8. The system of embodiment 7, further comprising a controller having a processor in data communication with the optical circuit, wherein the processor is configured to determine whether a signal received by the receiver matches the predetermined pattern of the pulsed signal, and wherein the processor is configured to issue a stop command when the signal received by the receiver does not match the predetermined pattern of the pulsed signal.
Embodiment 9. The system of any one of embodiments 1-8 and 10, further comprising a controller having a processor in data communication with the optical circuit, wherein the processor is configured to issue a stop command when the receiver does not receive an emitted optical signal.
Embodiment 10. The system of any one of embodiments 1-9, further comprising an indicator assembly coupled to the housing, wherein the indicator assembly is configured to provide visual indication of the operating state of the system.
Embodiment 11. A method comprising:
emitting an emitted optical signal by an emitter within a housing;
transmitting the emitted optical signal along an optical transmission pathway within the housing from the emitter towards a receiver via a mirror;
obstructing the optical transmission pathway resulting from engagement of a manual actuator;
identifying lack of receipt of the emitted optical signal by the receiver; and
issuing a stop command by a controller upon identification of the lack of receipt of the emitted optical signal.
Embodiment 12. The method of any one of embodiments 11 and 13-22, wherein obstructing the optical transmission pathway comprises translating a baffle across the optical transmission pathway.
Embodiment 13. The method of any one of embodiments 11-12 and 14-22, wherein obstructing the optical transmission pathway comprises translating the optical transmission pathway across a baffle.
Embodiment 14. The method of any one of embodiments 11-13 and 15-22, wherein obstructing the optical transmission pathway comprises translating the mirror.
Embodiment 15. The method of any one of embodiments 11-14 and 16-22, further comprising providing an electronic output signal to the controller by the receiver correlating to a received optical signal.
Embodiment 16. The method of embodiment 15, wherein identifying lack of receipt of the emitted optical signal by the receiver comprises determining that the emitted optical signal is not received by the receiver by a processor comparing the electronic output signal to the emitted optical signal and determining that the electronic output signal does not match the emitted optical signal.
Embodiment 17. The method of any one of embodiments 11-16 and 18-22, wherein the optical signal has a predetermined pattern.
Embodiment 18. The method of embodiment 17, wherein the electronic output signal has a different pattern than the predetermined pattern.
Embodiment 19. The method of any one of embodiments 11-18 and 20-22, further comprising withholding a stop command by a controller when the emitted optical signal is received by the receiver.
Embodiment 20. The method of 19, further comprising providing an electronic output signal to the controller from the receiver correlating to a received optical signal, wherein the emitted optical signal has a predetermined pattern and the electronic output signal has the same pattern as the predetermined pattern.
Embodiment 21. The method of any one of embodiments 11-20 and 22, further comprising issuing a run command by the processor.
Embodiment 22. The method of any one of embodiments 11-21, further comprising switching an indicator assembly from a first state of illumination to a second state of illumination upon the identifying lack of receipt of the emitted optical signal by the receiver.

It should also be noted that, as used in this specification and the appended claims, the phrase “configured” describes a system, apparatus, or other structure that is constructed to perform a particular task or adopt a particular configuration. The word “configured” can be used interchangeably with similar words such as “arranged”, “constructed”, “manufactured”, and the like.

All publications and patent applications in this specification are indicative of the level of ordinary skill in the art to which this technology pertains. All publications and patent applications are herein incorporated by reference to the same extent as if each individual publication or patent application was specifically and individually indicated by reference. In the event that any inconsistency exists between the disclosure of the present application and the disclosure(s) of any document incorporated herein by reference, the disclosure of the present application shall govern.

This application is intended to cover adaptations or variations of the present subject matter. It is to be understood that the above description is intended to be illustrative, and not restrictive, and the claims are not limited to the illustrative embodiments as set forth herein.

1. A system comprising:
a housing;
an optical circuit disposed in the housing, the optical circuit comprising an emitter configured to emit an emitted optical signal, a receiver configured to receive a received optical signal, and an optical transmission pathway extending from the emitter to the receiver, wherein the optical transmission pathway is indirect;
a manual actuator coupled to the housing having an engaged position and a disengaged position; and
a baffle fixed to the manual actuator, wherein the baffle obstructs the optical transmission pathway when the manual actuator is in the engaged position and the baffle is clear of the optical transmission pathway when the manual actuator is in the disengaged position.

2. The system of claim 1, wherein the emitter defines an emitter axis and the receiver defines a receiver axis and the emitter axis is parallel to the receiver axis.

3. The system of claim 1, wherein the optical transmission pathway comprises a first mirror.

4. The system of claim 3, wherein the optical transmission pathway comprises a second mirror perpendicular to the first mirror.

5. The system of claim 4, wherein engaging the manual actuator translates the baffle between the first mirror and the second mirror.

6. The system of claim 1, wherein the manual actuator is configured to maintain an engaged position until manual disengagement and the manual actuator is configured to maintain a disengaged position until manual engagement.

7. The system of claim 1, wherein the emitter is configured to emit a pulsed signal in a predetermined pattern.

8. The system of claim 7, further comprising a controller having a processor in data communication with the optical circuit, wherein the processor is configured to determine whether a signal received by the receiver matches the predetermined pattern of the pulsed signal, and wherein the processor is configured to issue a stop command when the signal received by the receiver does not match the predetermined pattern of the pulsed signal.

9. The system of claim 1, further comprising a controller having a processor in data communication with the optical circuit, wherein the processor is configured to issue a stop command when the receiver does not receive an emitted optical signal.

10. The system of claim 1, further comprising an indicator assembly coupled to the housing, wherein the indicator assembly is configured to provide visual indication of the operating state of the system.

11. A method comprising:
emitting an emitted optical signal by an emitter within a housing;
transmitting the emitted optical signal along an optical transmission pathway within the housing from the emitter towards a receiver via a mirror;
obstructing the optical transmission pathway resulting from engagement of a manual actuator;
identifying lack of receipt of the emitted optical signal by the receiver; and
issuing a stop command by a controller upon identification of the lack of receipt of the emitted optical signal.

12. The method of claim 11, wherein obstructing the optical transmission pathway comprises translating a baffle across the optical transmission pathway.

13. The method of claim 11, wherein obstructing the optical transmission pathway comprises translating the optical transmission pathway across a baffle.

14. The method of claim 11, wherein obstructing the optical transmission pathway comprises translating the mirror.

15. The method of claim 11, further comprising providing an electronic output signal to the controller by the receiver correlating to a received optical signal.

16. The method of claim 15, wherein identifying lack of receipt of the emitted optical signal by the receiver comprises determining that the emitted optical signal is not received by the receiver by a processor comparing the electronic output signal to the emitted optical signal and determining that the electronic output signal does not match the emitted optical signal.

17. The method of claim 11, wherein the emitted optical signal has a predetermined pattern.

18. The method of claim 17, wherein the electronic output signal has a different pattern than the predetermined pattern.

19. The method of claim 11, further comprising withholding a stop command by a controller when the emitted optical signal is received by the receiver.

20. The method of claim 19, further comprising providing an electronic output signal to the controller from the receiver correlating to a received optical signal, wherein the emitted optical signal has a predetermined pattern and the electronic output signal has the same pattern as the predetermined pattern.

21-22. (canceled)
